(19) United States
(12) Patent Application Publication
(10) Pub. No.: US 2012/0197570 A1
(43) Pub. Date: Aug. 2, 2012

(54) Measurement of Parameters Within an Integrated Circuit Chip Using a Nano-Probe

(76) Inventors: Mehran Ramezani, Laguna Niguel, CA (US); Vahid Ordoubadian, Newport Beach, CA (US)

(21) Appl. No.: 13/015,464

(22) Filed: Jan. 27, 2011

(51) Int. Cl. G06F 19/00; G01R 5/22; G01R 19/00

(52) U.S. Cl. 702/79; 324/76.11; 324/102; 324/105

(57) ABSTRACT

At least a method and a system are described for monitoring and measuring one or more parameters in an integrated circuit chip by way of receiving a first voltage, a second voltage, and a control signal. In a representative embodiment, the first voltage is used for powering a probe and the second voltage is used as a voltage reference for voltage measurement within the integrated circuit chip. In one or more representative embodiments, the one or more parameters measured comprise minimum and maximum voltage levels of a signal, sampled voltage levels of a signal, a period of a signal, a duty cycle of a clock signal, a jitter of a clock signal, and/or a temperature at a location within the integrated circuit chip.

### CROSS-REFERENCE TO RELATED APPLICATIONS/INCORPORATION BY REFERENCE

Not Applicable

### FEDERALLY SPONSORED RESEARCH OR DEVELOPMENT

Not Applicable

### MICROFICHE/COPYRIGHT REFERENCE

Not Applicable

### BACKGROUND OF THE INVENTION

Due to the limitation of power supplies and the intrinsic impedance of wires inside an integrated circuit chip, any on or off switching that occurs within the chip will have a negative effect on one or more voltage levels provided by one or more power supplies. For example, high frequency switching in one part of a circuit may have a significant effect on the power line voltages within the integrated circuit chip. Furthermore, each of the one or more of the affected power line voltages may exhibit a noticeable voltage ripple which causes the distribution of noise throughout the integrated circuit. Additionally, any imperfections in integrated circuit fabrication may significantly affect such noise and may result in adverse effects on the duty cycle and periodicity of any clock generated or utilized within the integrated circuit. Furthermore, the electrical and mechanical characteristics of commercial integrated circuit packages prevent the ability to monitor one or more parameters of signals during debugging and/or verification of the integrated circuit chip.

The limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

Various aspects of the invention provide a method and a system of performing monitoring and measurement of one or more parameters of a signal located within an integrated circuit chip.

The various aspects and representative embodiments of the method and system are substantially shown in and/or described in connection with at least one of the following figures, as set forth more completely in the claims which follow.

These and other advantages, aspects, and novel features of the present invention, as well as details of illustrated embodiments, thereof, will be more fully understood from the following description and drawings.

### BRIEF DESCRIPTION OF THE DRAWINGS

FIG. 1 illustrates a diagram of a circuit in an integrated circuit chip in which one or more voltages monitored and measured over time in accordance with an embodiment of the invention.

FIG. 2 illustrates a diagram of a circuit in an integrated circuit chip in which a clock's jitter is monitored and measured in accordance with an embodiment of the invention.

FIG. 3 illustrates a block diagram of a system used for monitoring, measuring, and sensing various parameters within an integrated circuit chip in accordance with an embodiment of the invention.

FIG. 4 is a detailed block diagram of a system used for monitoring, measuring, and sensing various parameters within an integrated circuit chip in accordance with an embodiment of the invention.

FIG. 5 is a block diagram of a probe tip circuitry used in voltage sampling in accordance with an embodiment of the invention.

FIG. 6 is a block diagram for a probe tip storage circuitry in accordance with an embodiment of the invention.

FIG. 7 is a graph of voltage over time for a signal measured by a probe in accordance with an embodiment of the invention.

FIG. 8 is a graph of voltage over time for a signal measured by a probe in accordance with an embodiment of the invention.

FIG. 9 is a block diagram of a probe tip circuitry used in measuring clock jitter in accordance with an embodiment of the invention.

FIG. 10 is a detailed circuit diagram of the ring oscillator and a register of a probe tip circuitry in accordance with an embodiment of the invention.

FIG. 11 is an operational flow diagram of a method for measuring one or more parameters of a signal in an integrated circuit chip in accordance with an embodiment of the invention.

### DETAILED DESCRIPTION OF THE INVENTION

Various aspects of the invention can be found in a method and a system of performing monitoring and measurement of one or more parameters of a signal located within an integrated circuit chip. The integrated circuit chip may comprise an application specific integrated circuit (ASIC), for example. By way of including a small probe within the integrated circuit or ASIC, the various aspects of the invention make it possible to perform in-situ (in place) monitoring and measurement of such parameters without affecting the signal to be monitored or measured. For example, the one or more parameters may comprise a signal's voltage measured over time. The one or more parameters may comprise a clock's period, its duty cycle, and its jitter, for example. Furthermore, the one or more parameters may comprise a temperature of the integrated circuit or ASIC measured at the location of a probe. Each of the one or more probes may comprise one or more circuits. In a representative embodiment, the integrated circuit may comprise a plurality of probes which are used to monitor and measure a plurality of parameters corresponding to a plurality of signals within the integrated circuit. Furthermore, the various aspects of the invention facilitate the use of the one or more probes as a diagnostic or sensory tool during pre-production and post-production of the integrated circuit. Therefore, the various aspects of the invention provide for one or more probes that serve a dual purpose. In a representative embodiment, the one or more probes may be used as a “debugging” tool in pre-production as well as a sensor in post-production.

In a representative embodiment, the probe occupies a very small area in the integrated circuit and is placed strategically near specific signals of interest. Therefore, the probe may be described as a “nano-probe.” The probe may be configured and adapted for use in measuring voltages of the one or more signals of interest. For example, the probe may be used to measure the lowest and highest voltage levels during a particular period of time. In a representative embodiment, the probe may be used to measure a minimum and a maximum voltage of a signal in the integrated circuit. Furthermore, the probe may be used to measure a series of sampled voltage levels of a signal in the integrated circuit. Furthermore, with the addition of an optional memory, the probe may be used to capture a waveform of voltage over time. The probe may comprise a small mixed signal circuitry. In a representative embodiment, the probe may comprise circuitry that measures a clock's period, duty cycle, and jitter.

In a representative embodiment, a probe control circuitry may be used to provide control for the one or more probes located within the integrated circuit. The probe control circuitry may be used to configure each of the one or more probes in the integrated circuit chip or ASIC. In a representative embodiment, the probe control circuitry may receive any data generated by each of the one or more probes. The probe control circuitry may shift out the data through any debug interface such as a JTAG interface for example. The data may be transmitted through the JTAG interface to external test equipment. The external test equipment may provide the one or more probes with a power supply voltage, one or more reference voltages, and a timing control signal. The timing control signal may be used to indicate when to start and stop measurement of a particular parameter. For example, the rising edge of a pulse of the timing control signal may be used to initiate the start of a measurement period and the falling edge of the pulse may be used to initiate the end of the measurement period. The timing control signal may also be used to initiate the start of data transfer to the probe control circuitry from the one or more probes. In a representative embodiment, the width of the pulse of a timing control signal is configured by the external test equipment. In a representative embodiment, data transfer from the one or more probes occurs when the timing control signal is not active or the timing control signal is in its low state. In a representative embodiment, the high pulse state or “high pulse” of the timing control signal will be of much shorter duration than its low pulse state. Furthermore, the various aspects of the invention allow the probe control circuitry to communicate with any processor native to the integrated circuit chip.

In a representative embodiment, the integrated circuit chip, containing the one or more probes and probe control circuitry, communicates with external test equipment via the JTAG interface. The probe control circuitry receives power through two power supplies pins. One of the two pins is used for receiving a first voltage while the other pin is used for receiving a second voltage. The third pin is used for receiving the previously mentioned timing control signal. The two voltages may be used for powering the one or more probes and as a reference voltage for measuring one or more parameters of the signals under study. The data collected over the debug interface (JTAG) may be stored in a database in a storage media of a computer. The computer may perform statistical analysis, interpretation, and presentation of the data. The information may be displayed to a user.

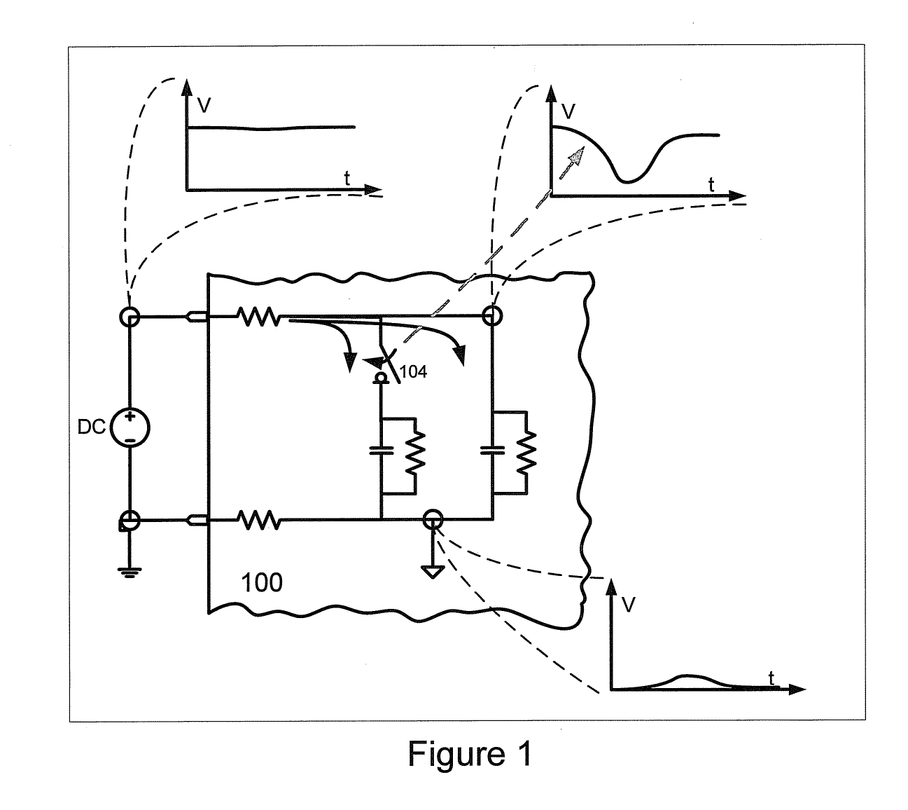

FIG. 1 illustrates a diagram of a circuit in an integrated circuit chip 100 in which one or more voltages monitored and measured over time in accordance with an embodiment of the invention. As illustrated, the exemplary circuit comprises a switch 104 and a number of resistors and capacitors. An external power supply provides DC power to the circuit within the integrated circuit chip 100. The power supply may be part of an external test equipment. FIG. 1 illustrates the effects of a power glitch and ground bounce which may occur during a current rush. The current rush results when the switch 104 is toggled to close the circuit. The effects of the current rush and ground bounce is further illustrated by way of the three graphs in FIG. 1. The graphs represent voltage over time at three different points on the circuit. In a representative embodiment, one or more probes may be used to measure the voltage at each of these points along the circuit. For example, one probe is placed at the positive end of the resistors while another probe is placed at a ground node of the circuit. By way of placing the probes, the voltages at these points may be monitored and measured in accordance with the various aspects of the present invention. The waveforms may be generated and displayed as illustrated in FIG. 1.

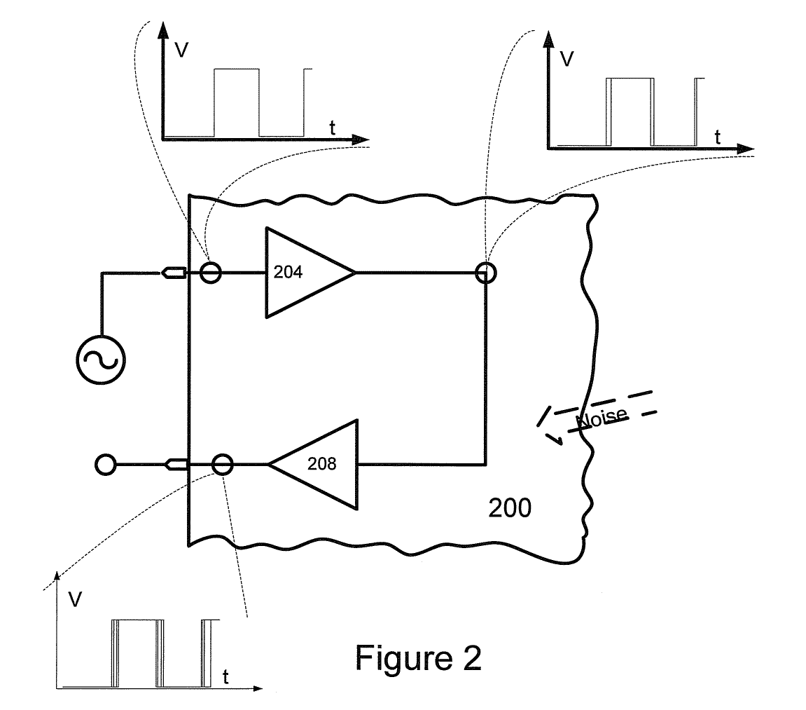

FIG. 2 illustrates a diagram of a circuit in an integrated circuit chip 200 in which a clock's jitter is monitored and measured in accordance with an embodiment of the invention. As illustrated, the exemplary circuit comprises a first buffer 204 and a second buffer 208. An external waveform generator provides a clock to the circuit within the integrated circuit chip 200. The external waveform generator may be part of an external test equipment. In addition, noise may be introduced to the integrated circuit chip 200 from an adjacent switching circuit. FIG. 2 illustrates the effects of clock jitter due to induced noise. As illustrated, the three graphs represent voltage measured over time at three different points along the circuit. In a representative embodiment, a probe may be used to measure the voltage at each of these points on the circuit. For example, a first probe is placed at an input pin of the integrated circuit chip corresponding to the input of the first buffer 204. Furthermore, for example, a second probe is placed at the output of the first buffer 204 while a third probe is placed at the output of the second buffer 208. By way of using these probes, the observed jitter may be monitored and measured at various points of interest within the integrated circuit chip 200.

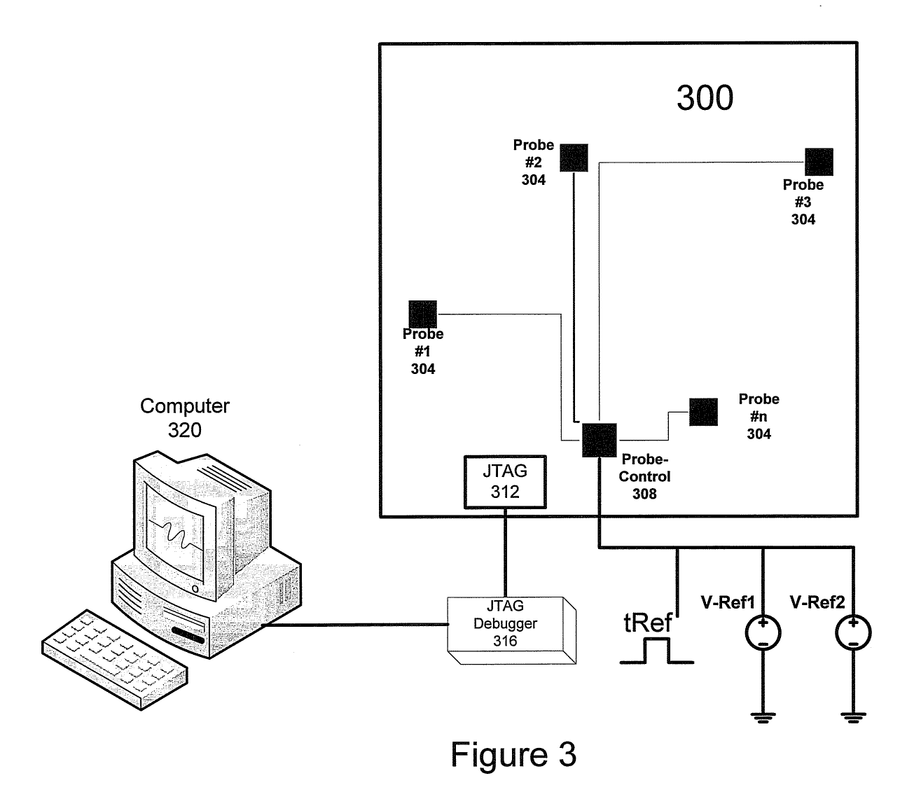

FIG. 3 illustrates a block diagram of a system used for monitoring, measuring, and sensing various parameters within an integrated circuit chip 300 in accordance with an embodiment of the invention. The system comprises a plurality of probes 304 placed within the integrated circuit chip 300. The probes 304 may be placed strategically at various locations where measurements of particular parameters are desired. The parameters may comprise voltage, current, temperature, and jitter, for example. The integrated circuit chip 300 may comprise an ASIC (application specific integrated circuit), for example. The system further comprises a probe control circuitry 308 which is used to configure, control, and collect data from all probes within the integrated circuit chip 300. The probe control circuitry 308 may comprise any type of digital logic circuitry used for configuring, controlling, and collecting data from all probes within the integrated circuit chip 300. As illustrated in FIG. 3, the probe control circuitry 308 is communicatively coupled to each of the probes 304. The system further comprises a data interface such as a JTAG interface 312 which is communicatively coupled to an external test equipment. The JTAG interface 312 may transmit the data obtained from the probes to the external test equipment. The external test equipment may comprise a device such as a JTAG debugger 316 as illustrated in FIG. 3. The external test equipment is communicatively coupled to a computer 320. The received data may be further processed and displayed by the computer 320 as illustrated in FIG. 3. The received data may be statistically analyzed by the computer 320 and one or more reports may be generated for use by a user of the computer 320.

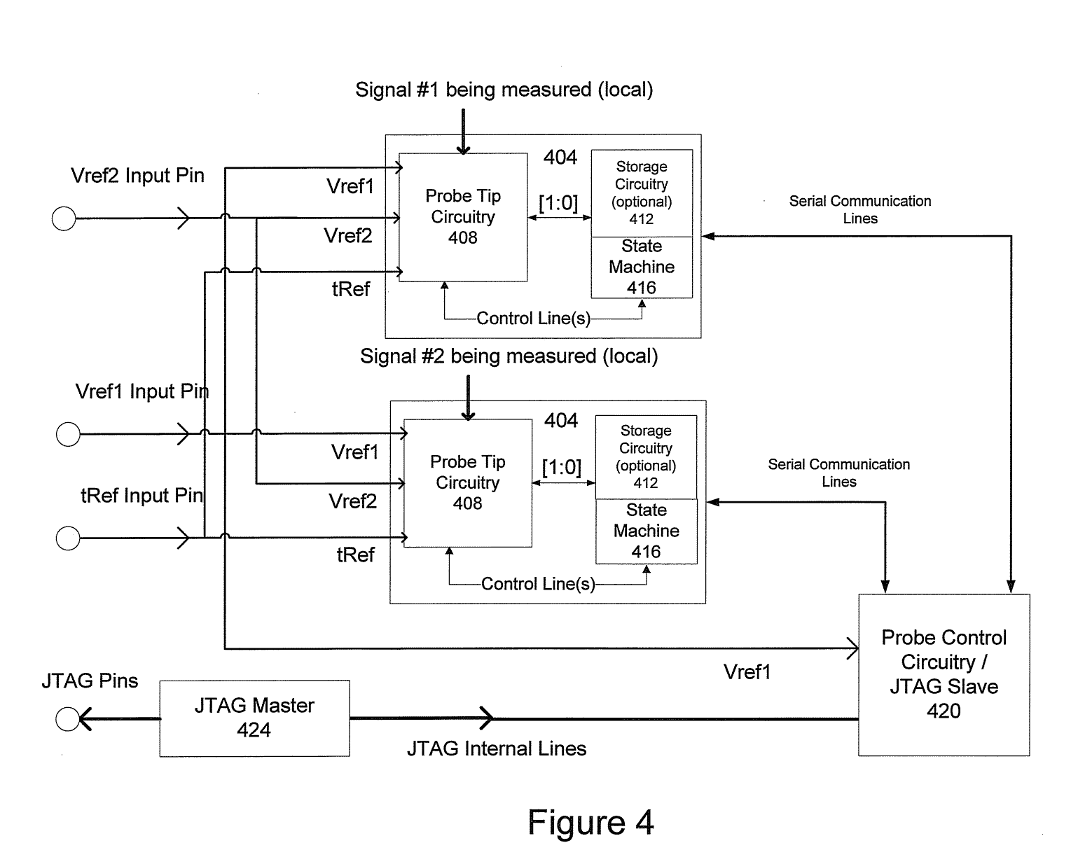

FIG. 4 is a detailed block diagram of a system used for monitoring, measuring, and sensing various parameters within an integrated circuit chip in accordance with an embodiment of the invention. The system comprises a circuit embedded within an integrated circuit chip, for example. In the embodiment illustrated in FIG. 4, the circuit comprises two probes 404 and probe control circuitry 420 for controlling the probes 404. In other embodiments, there may be any number of probes utilized as required by the monitoring and measurement requirements associated with the integrated circuit chip. Each of the two probes 404 comprises a probe tip circuitry 408 communicatively coupled to a storage circuitry 412 and state machine 416. The probe tip circuitry 408 may comprise a digitizer, for example. As illustrated, each probe tip circuitry 408 may be in contact at a desired point on a circuitry within the integrated circuit chip. The probe tip circuitry receives a signal (i.e., signals #1 and 2 as illustrated) of which a parameter of the signal is measured by the probe tip circuitry 408. The probe tip circuitry 408 may store data, obtained from its measurement of one or more parameters, into an optional storage circuitry 412. The storage circuitry 412 may comprise any type of memory. The size of the memory may be varied based on data storage requirements of a probe. The probe tip circuitry 408 may communicate with the state machine 416 via one or more control lines as shown. A serial communications protocol may be used to configure each probe before each measurement is made. The probe control circuitry 420 may be used to configure each probe by way of using the serial communications protocol. The serial communications protocol may be used to shift out the data collected by the probe tip circuitry 408 over one or more serial communications lines after measurement has been performed. The serial communications protocol may utilize a variable clock to minimize its impact on neighboring circuits and yet be able to shift data out fast enough to empty the data stored in the storage circuitry 412 in preparation for a next measurement. The data transmitted from a probe is transmitted to the probe control circuitry 420. The probe control circuitry 420 may comprise a JTAG slave. The probe control circuitry 420 may transmit the measured data to a JTAG master 424, which communicates with the JTAG slave such that the measured data may be transmitted to external test equipment. The JTAG master 424 may act as an interface to the external test equipment. The probe tip circuitry 408 may comprise circuitry for measuring any type of parameter of any signal within the integrated circuit chip. For example, the probe tip circuitry 408 may be used to measure voltage levels and jitter over a period of time. In addition, the probe tip circuitry 408 may be configured to measure the temperature of an area in which it is placed. In one embodiment, the probe tip circuitry 408 may be used to measure a clock signal's voltage levels to determine a clock's period or duty cycle, for example. Furthermore, the jitter of a clock may be determined. In a representative embodiment, only a single probe control circuitry 420 is needed to configure each probe of a plurality of probes in an integrated circuit chip. Also shown in FIG. 4 are input pins corresponding to the integrated circuit chip. In a representative embodiment, two voltages are supplied through two voltage pins, Vref1 and Vref2, while a timing control signal tRef is supplied through a separate pin and is used to control the beginning and the end of a particular measurement. Vref1 may be used to supply power to the probe tip circuitry 408 and the probe control circuitry 420. Vref2 may be used as a reference voltage for voltage measurement. Vref2 may also be used in one or more circuits located within the probe tip circuitry 408. For example, Vref2 may be used as a power source for one or more comparators used in the probe tip circuitry 408. In a representative embodiment, the rising edge of the tRef signal initiates the start of a measurement while the falling edge initiates the end of the measurement. The width of the tRef pulse may be accurately generated by the external test equipment. In a representative embodiment, the data transfer from the probe 404 to the probe control circuitry 420 occurs while control signal tRef is not active or in its low voltage state. The system which utilizes the one or more probes and probe control circuitry may utilize no more than three input pins. In a representative embodiment, it may be possible to consolidate two of the reference voltage pins by way of using a single pin. In addition, it may be possible to multiplex these voltage reference signals with other analog signals. In a representative embodiment, a host processor native to the integrated circuit (or ASIC) may communicative with the probe control circuitry 420. The processor may request the probe control circuitry 420 to configure and read the collected data from the probe tip circuitry 408. In a representative embodiment, after the initial development and debug phase of the ASIC, and during the actual use of the ASIC, an interface for interfacing the probe control circuitry 420 with the native host processor will replace the JTAG interface. The interface is used for transmitting the measured data obtained from a probe tip circuitry 408 to the native host processor for further processing. As the processor may be incorporated within the integrated circuit chip, the processor may be used in processing any data obtained from one or more probes after the integrated circuit chip has been fabricated and may be used during normal operation of the integrated circuit chip. The native processor may output any if the processed data through one or more available pins of the integrated circuit chip.

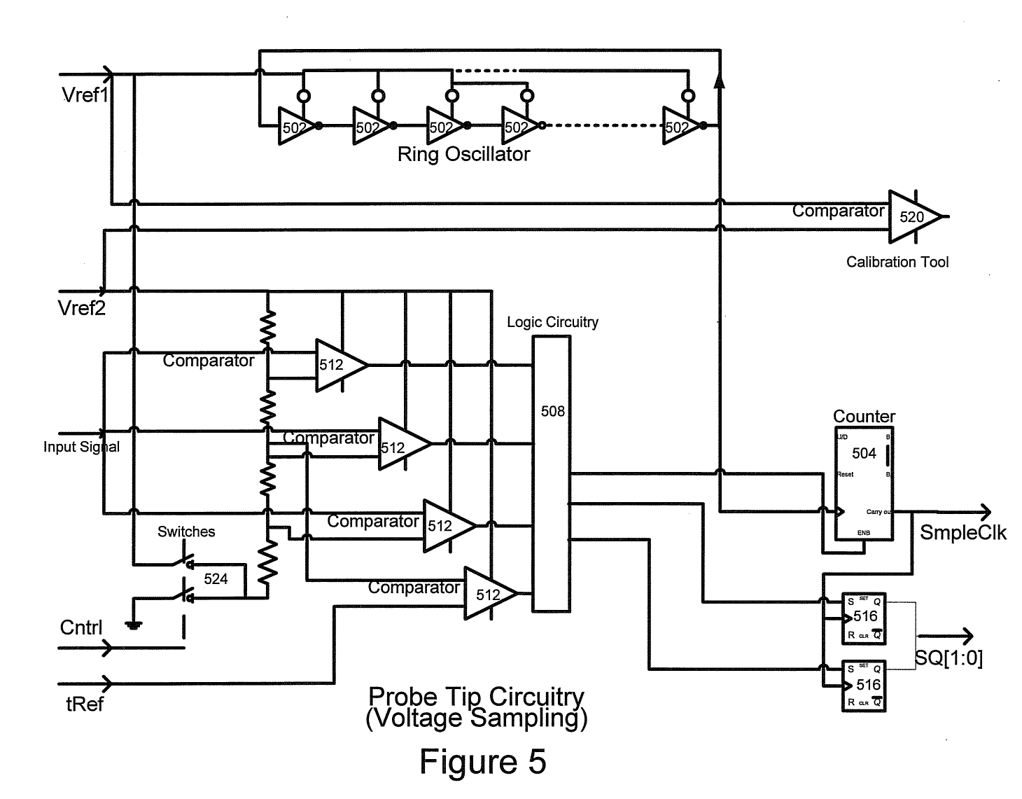

FIG. 5 is a block diagram of a probe tip circuitry used in voltage sampling in accordance with an embodiment of the invention. In a representative embodiment, the probe tip circuitry comprises an eleven element ring oscillator and five precision high speed comparators. The elements of the ring oscillator may be described as delay elements because each element contributes to a time delay in the ring oscillator. The ring oscillator may comprise an odd number of elements. For example, the elements may comprise inverters 502. In one representative embodiment, the ring oscillator may comprise a total of eleven inverters 502. In an alternate embodiment, the ring oscillator may comprise a total of thirteen inverters 502. The frequency of the ring oscillator may be determined by Vref1, the junction temperature of the ring oscillator elements, and the integrated circuit fabrication process. In accordance with the various aspects of the invention, the ring oscillator oscillates at frequency ranges between 1 GHz and 4.5 GHz. As illustrated, the output of the ring oscillator provides an input to the trigger of a counter 504. The propagation delay (i.e., gate delay) in each element (i.e., inverter) is governed by Vref1, the element junction temperature, and the chemical composition (fabrication process) of the element. The frequency of the ring oscillator may be defined by the following equation for an embodiment that utilizes thirteen elements (i.e., gate delay elements) in the ring oscillator:

$$\begin{matrix}Freq = f ( Vref {1}^{2} , Junction Temp , Process ) \\ = \frac{1}{GateDelay \times 13} \\ = \frac{1}{g ( Vref {1}^{2} , Temp , P ) \times 13} ,\end{matrix}$$

where P denotes Process, Temp denotes junction Temperature of a transistor in the ring oscillator, and Gate Delay denotes an average time delay through an element of the ring oscillator, such as a delay through the inverter 502. For a particular integrated circuit chip, P, the fabrication process used, comprises a fixed value obtained through experimentation.

For example, a 4 GHz frequency may be generated by a thirteen stage ring oscillator constructed from a 65 nm CMOS (typical process) when Vref1 is set to 1.2V and the junction temperature is 25° C. FIG. 5 illustrates an exemplary voltage divider implemented using a series of four resistors. The voltage divider divides the voltage difference between Vref2 and ground or Vref2 and Vref1 in fourths. Switching between ground and Vref1 may be implemented by way of a pair of switches 524, as shown in FIG. 5. A switch of the switches 524 may be toggled by way of a control signal (Cntrl) as illustrated. For example, use of the switches 524 may allow selection of Vref1 or ground. Also illustrated are a set of four comparators 512 for comparing the voltage levels of a signal under study against the four reference voltages generated by the voltage divider. The outputs of the comparators 512 are communicatively coupled to a combinatorial logic circuitry 508. The logic circuitry 508 may comprise any number of logic gates. The logic circuitry 508 translates the outputs of the comparators to indicate the voltage level of the signal under study. For example, a binary value of 11 indicates that the voltage level, Vsig, is in its highest detectable range

$$( Vref 2 \geq Vsig > \frac{3}{4} * VRef 2 ) .$$

On the other hand, for example, a binary value of 10 indicates that the voltage level, Vsig, is in the next highest detectable range

$$( \frac{3}{4} * Veref 2 > Vsig > \frac{1}{2} * Vref 2 ) .$$

Likewise, binary values for 01 and 00 would indicate that the voltage level, Vsig, lies in their respective ranges. The logic circuitry 508 may generate a signal that enables and disables the counter 504. In a representative embodiment, the logic circuitry 508 generates an enable signal to the counter 504 based on the voltage level of the tRef signal. For example, the counter is enabled when the level of the tRef signal is at least 50% of the voltage range of the tRef signal. The logic circuitry 508 controls the capture and storage of the collected data. While not shown in FIG. 5, the logic circuitry 508 may facilitate storing the lowest voltage value and the highest voltage value of a waveform voltage measurement along with a snapshot of one or more parameters associated with the counter 504. This data may be stored into a memory such as the optional storage circuitry described in connection with FIG. 4. The logic circuitry 508 may output two bit values corresponding to the voltage measurement of the signal. The two bit values may be stored in two flip-flops 516. The two bit values may be sequentially captured by the flip-flops 516 the output rate of the counter 504. Furthermore, the lowest voltage value and the highest voltage value of a measurement may be further stored in a separate memory (not shown) for further processing. A storage circuitry may be implemented within the probe, as was discussed in FIG. 4, to allow the probe tip circuitry to store any of the measured data. Further processing of the stored data may take place at a processor native to the integrated circuit chip or outside of the integrated circuit chip, such as at a computer communicatively coupled to the integrated circuit chip. A comparator 520 in the probe tip circuitry of each probe may be used to compare the actual voltage values of Vref1 and Vref2 at a probe tip. The comparator 520 is used to determine when the internal values of Vref1 and Vref2 are equal to each other. Therefore, it is possible to calibrate Vref2 to Vref1 at the probe tip of a probe.

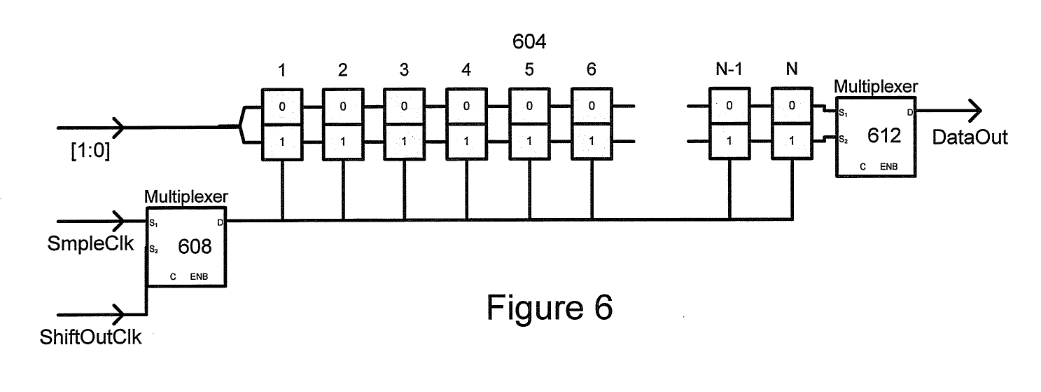

FIG. 6 is a block diagram for a probe tip storage circuitry in accordance with an embodiment of the invention. The probe tip storage circuitry may correspond to the optional storage circuitry previously described in connection with FIG. 4. The probe tip storage circuitry comprises a number of paired flip-flops 604 (1, 2, . . . , N) wherein each pair is capable of storing two bits. FIG. 6 illustrates a total of N stages. The flip-flops 604 at the Nth stage provide outputs to a multiplexer 612. The multiplexers 608, 612 are used to shift each bit serially through the flip-flops 604 to a probe control circuitry, for example. The probe control circuitry may subsequently shift the data to an external test equipment and/or a computer where the data is further stored, analyzed, and displayed to a user.

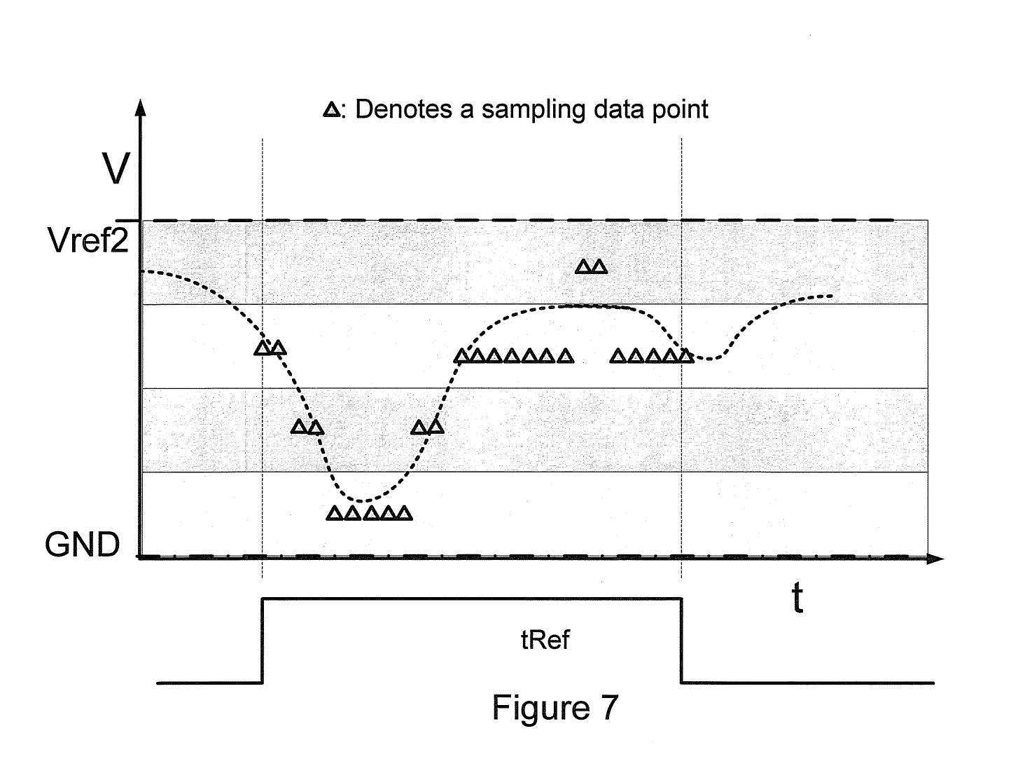

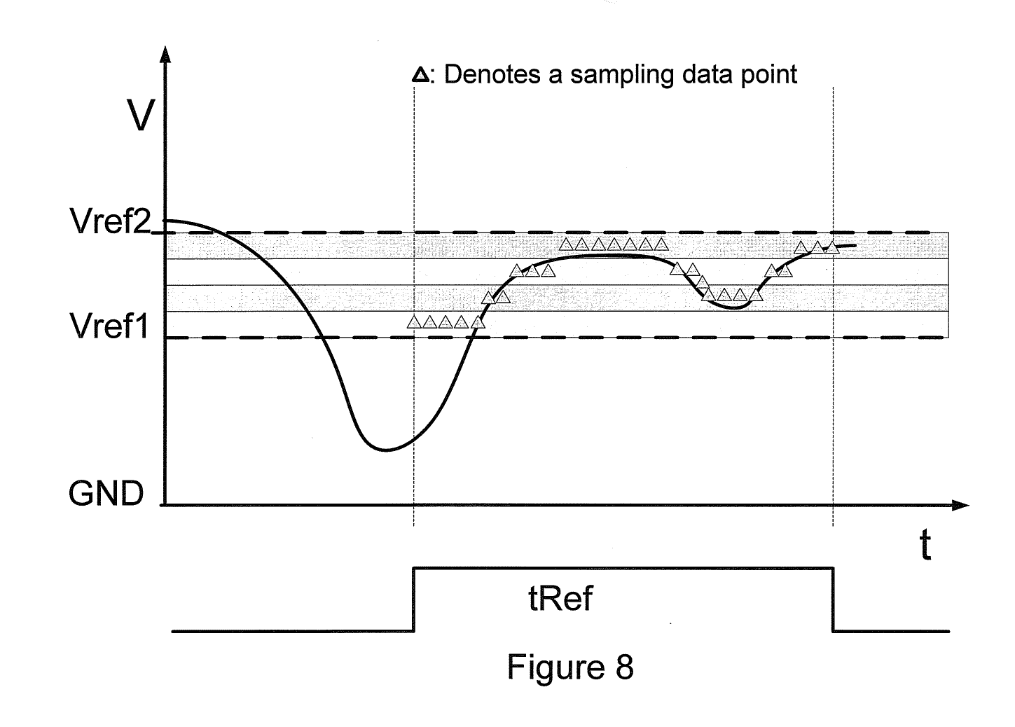

By way of communicating via the JTAG interface, the configuration of the probe tip circuitry may be changed to utilize one or more voltage ranges for determining the level of the input signal, Vsig. In a representative embodiment, one of two voltage ranges is used for determining the level of the input signal. FIGS. 7 and 8 are graphs of voltage over time for a signal measured by a probe in accordance with an embodiment of the invention. In FIG. 7, a first range is illustrated that comprises values between Vref2 and ground while in FIG. 8, a second range is illustrated that comprises values between Vref2 and Vref1. The voltage range in either instance is divided into four equal regions. Thus, when the input signal is sampled (as denoted by the sampled data points during the tRef pulse width, as illustrated in FIGS. 7 and 8), it may lie within any one of the four regions. As shown in FIG. 8, the accuracy of the measurement is considerably increased since the resolution is better. As illustrated in FIG. 8, by way of keeping Vref2 constant and subsequently increasing Vref1 incrementally, a more accurate measurement of the input signal voltage level may be constructed in a desired voltage range. The history can be used to statistically characterize the voltage level patterns associated with the input signal being measured.

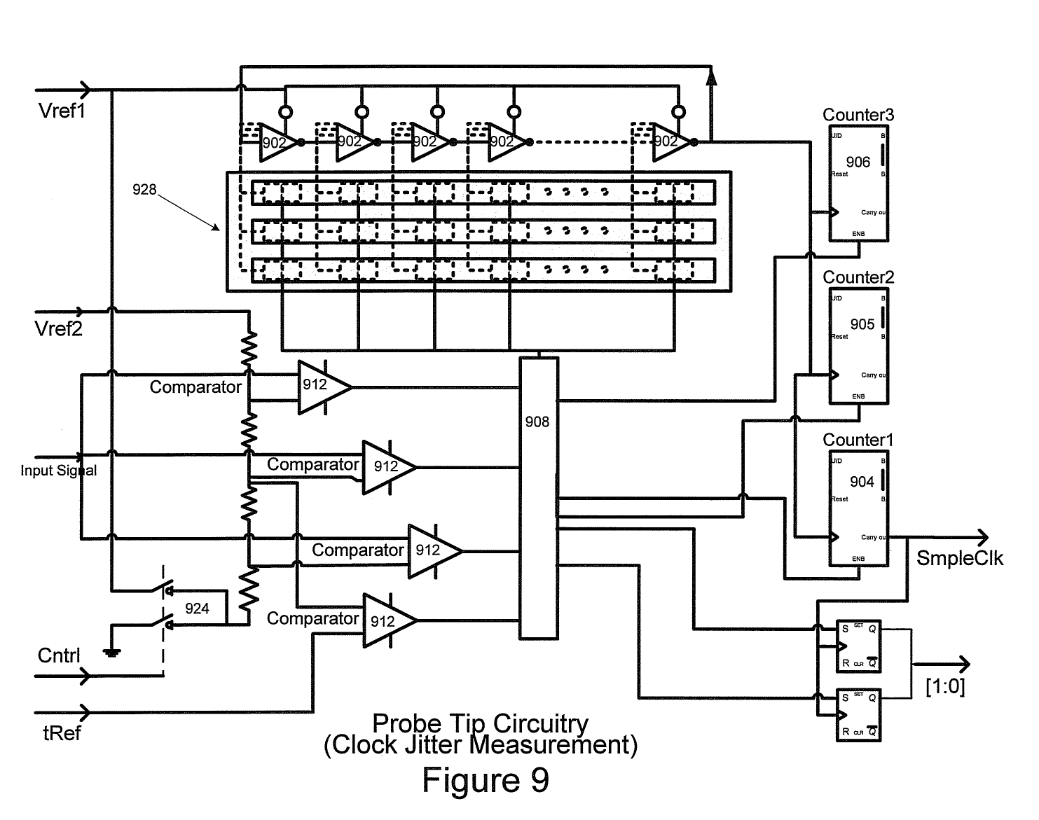

FIG. 9 is a block diagram of a probe tip circuitry used in measuring clock jitter in accordance with an embodiment of the invention. The probe tip circuitry shown in FIG. 9 may be used to measure a periodic waveform's period, duty cycle, and jitter. Compared to the probe tip circuitry presented in FIG. 5, the probe tip circuitry of FIG. 9 incorporates a set of five dual bit multi-stage registers 928. Each of the five dual bit multi-stage registers comprises 22 stages wherein each stage comprises a pair of flip-flops. Switching between ground and Vref1 at one end of the resistive voltage divider may be implemented by way of a pair of switches 924, as shown in FIG. 9. A switch of the pair of switches 924 may be toggled by way of a control signal (Cntrl) as illustrated. Similar to the probe tip circuitry previously described in connection with FIG. 5, FIG. 9 illustrates a set of four comparators 912 which output to a combinatorial logic circuitry 908. The combinatorial logic circuitry 908 translates the outputs of the comparators to indicate the voltage level of the signal under study. For example, a binary value of 11 indicates that the voltage level of a signal being measured, Vsig, is in the highest detectable range

$$( Vref 2 \geq Vsig > \frac{3}{4} * VRef 2 ) .$$

On the other hand, for example, a binary value of 10 indicates that the voltage level, Vsig, is in the next highest detectable range

$$( \frac{3}{4} * Veref 2 > Vsig > \frac{1}{2} * Vref 2 ) .$$

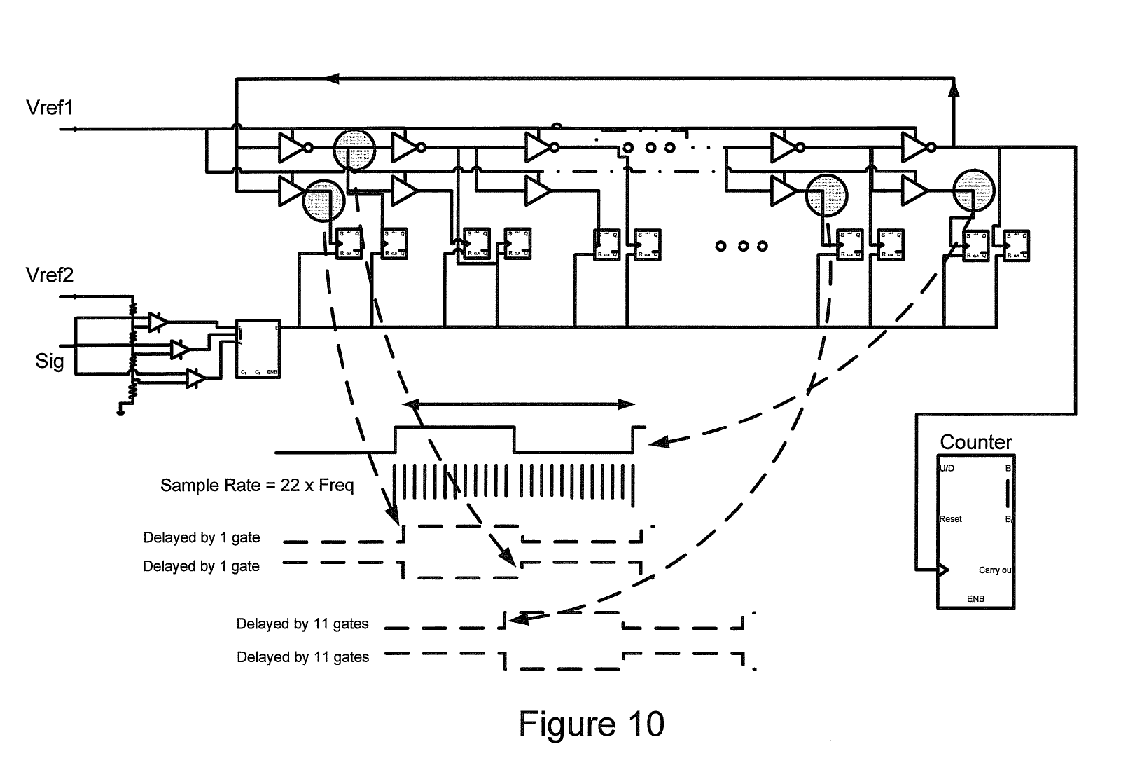

Likewise, binary values for 01 and 00 will indicate that the voltage level, Vsig, lies in their respective ranges. The logic circuitry 908 may generate a signal that enables and disables the counter 904. In a representative embodiment, the logic circuitry 908 generates an enable signal to the counter 904 based on the voltage level of the tRef signal. For example, the counter is enabled when the level of the tRef signal is at least 50% of the voltage range of the tRef signal. Furthermore, the logic circuitry 908 enables the detection of the rising and falling edge of the signal under study through the five dual bit multi-stage registers 928. The logic circuitry 908 also starts and stops the counters 904, 905, 906. Counter #1 904 comprises a counter that counts the number of ring oscillator clocks while the tRef signal is high. In a representative embodiment, the count provided by Counter #1 904 is only accurate to ±1 (plus or minus one) ring oscillator clocks. Thus, Counter #1 904 is used to measure the duty cycle of the tRef signal. Counter #2 905 comprises a counter that counts the number of ring oscillator clocks between the two subsequent rising edges of the Vsig signal while the tRef signal is high. In a representative embodiment, the count provided by Counter #2 905 is only accurate to ±1 (plus or minus one) ring oscillator clocks. Thus, Counter #2 905 is used to measure one cycle time or one period of the Vsig signal. Counter #3 906 comprises a counter that counts the number of ring oscillator clocks between the falling and the rising edges of the Vsig signal while the tRef signal is high. In a representative embodiment, the count provided by Counter #3 is only accurate to ±1 (plus or minus one) ring oscillator clocks. Thus, Counter #3 906 is used to measure the time when Vsig is high. To attain a one gate delay accuracy, both the tRef control signal and Vsig will be continuously sampled into the five dual bit multi-stage registers wherein each register comprises a series of 11 pairs of flip-flops (total of 22 flip-flops) at a rate of 22 times the ring oscillator's frequency. As will be shown FIG. 10, each pair of flip-flops in the series is clocked with a one gate delay separation from the next pair in the series. Each of the registers 928 may determine the elapsed time between a rising or falling edge and rising edge of the next ring oscillator clock. The registers 928 may be controlled by the logic circuitry 908. The logic circuitry 908 may employ a state machine that starts or stops clocking these registers 928 as soon as a transitional rising or falling edge of a signal (e.g., a transition voltage level from 50% of Vref2 to 75% of Vref2) is detected. When the data in one or more registers is shifted out to the external test equipment via the JTAG interface, the external test equipment may analyze the data and determine the time between two time points in terms of half of a gate delay. In a representative embodiment, the output of Counter #1 904 provides a measurement of the pulse width of the tRef timing control signal. In a representative embodiment, the output of Counter #2 905 provides a measurement of one period of Vsig (the signal being measured). In a representative embodiment, the output of Counter #3 906 provides a measurement of the time when Vsig is high. While the previously described embodiment discloses a register comprising 11 stages of paired flip-flops comprising a total of 22 flip-flops, it is contemplated that in other embodiments any odd number of stages may be used. For example, in another representative embodiment, each of the five registers comprises 13 stages of paired flip-flops (for a total of 26 flip-flops) which corresponds to a thirteen stage (or element) ring oscillator. Thus, the various aspects of the invention utilize a plurality of registers in which each register contains the same number of stages as the number of elements used in the ring oscillator.

FIG. 10 is a detailed circuit diagram of the ring oscillator and a register of a probe tip circuitry in accordance with an embodiment of the invention. The register shown in FIG. 10 may correspond to one of the set of five dual bit multi-stage registers 928 that was previously described in connection with FIG. 9. Each of the five registers in the probe tip circuitry comprises a total of eleven flip-flop pairs. Therefore, in this representative embodiment, a total of 22 flip-flops are used to implement a register. As illustrated, each stage of the ring oscillator provides an inverted output and a non-inverted output. An inverted output is provided to a first flip-flop of a pair of flip-flops in a stage of the register. A non-inverted output is provided to a second flip-flop of the pair of flip-flops in the stage of the register. The output of the ring oscillator is provided to the trigger input of an exemplary counter as shown in FIG. 10. FIG. 10 also provides timing diagrams at various points along the ring oscillator circuitry as indicated by the arrows. A timing diagram shows that the register is sampled at 22 times the ring oscillator frequency. The timing diagram also illustrates the gate delay at various points along the ring oscillator circuitry. By way of using the five registers, the accuracy of the measured parameter improves by 22 times since the non-inverted output of a ring oscillator element is input to a first flip-flop of a pair of flip-flops in a stage of the register while the inverted output of the ring oscillator element is input to a second flip-flop of the pair of flip-flops in the same stage of the register. The non-inverted and inverted outputs provided by the next element in the ring oscillator are similarly input into the next stage or next flip-flop pair of the same register as illustrated in FIG. 10. Likewise, successive non-inverted and inverted outputs of an element are provided as inputs to the next flip-flop pair in the register. Therefore, each of the eleven flip-flop pairs of the next register (i.e., the second register of five registers) receives non-inverted and inverted outputs from each of the elements in the ring oscillator. The non-inverted and inverted outputs may be obtained from any element of the ring oscillator. For example, the first pair of flip-flops of the second register may receive outputs may be obtained from the second element of the ring oscillator. In this manner, sub-sampling of Vsig or the tRef timing control pulse signal may be accomplished at a frequency that is 22 times the ring oscillator frequency. Consequently, the jitter may be measured more accurately at a resolution that corresponds to one-half the gate (or element) delay of the ring oscillator.

Since the ring oscillator clock frequency is affected by noise presented by Vref1 and the variation in junction temperature of the transistors in the elements (e.g., inverters) of the ring oscillator, the stability of the ring oscillator clock may suffer. However, the average gate delay of each the ring oscillator elements may be determined by comparing the pulse width of the tRef signal as measured by the probe (or nano-probe) against the pulse width generated by the external test equipment. For example, for each pulse width measurement, a value from a probe may be measured within the pulse width duration of the tRef timing control signal, measured in units of ½ gate delays. The number of elements in the ring oscillator is known. For example, there may be a total of eleven elements in the ring oscillator. Thus, by way of comparing the actual value (as determined by the external test equipment) of the tRef signal's pulse width by the pulse width as measured from a probe, an average value for the gate delay (or element delay associated with each element of the exemplary 11 element ring oscillator) may be determined. Therefore, the accuracy of the probe with respect to its jitter measurement capability may be maintained. The probe may be calibrated in this manner for each tRef signal's period.

In the multi-element ring oscillator, the ring oscillator element delay determines frequency or period of the ring oscillator. The frequency of the ring oscillator depends on the power source, junction temperature, and the chemical composition of the transistors utilized in each element (or gate) of the ring oscillator. The frequency may be defined by the following function:

Freq=f(Vref1²,Junction Temp,Process)

It is contemplated that all fabricated integrated circuit chips or ASICs are tested by external test equipment such as an Automatic Test Equipment (ATE) before being shipped to end users or customers. An ASIC equipped with one or more probes may be connected to known power supplies and signal generators such that the accuracy of the voltages and timing it provides (Vref1, Vref2 and tRef) is guaranteed by the ATE. The various aspects of the invention allow the determination of chemical composition variation of the transistors (fabrication process) in an integrated circuit chip by way of the ATE using a probe embedded in the integrated circuit or ASIC. Given an ASIC's specific fabrication process and the value of Vref1, the junction temperature of a transistor in the ring oscillator may be determined by reading a probe. In a representative embodiment, a processor within or native to the ASIC may be used to calculate the junction temperature by way of a look-up table. The look-up table may be stored in a memory communicatively coupled to the processor.

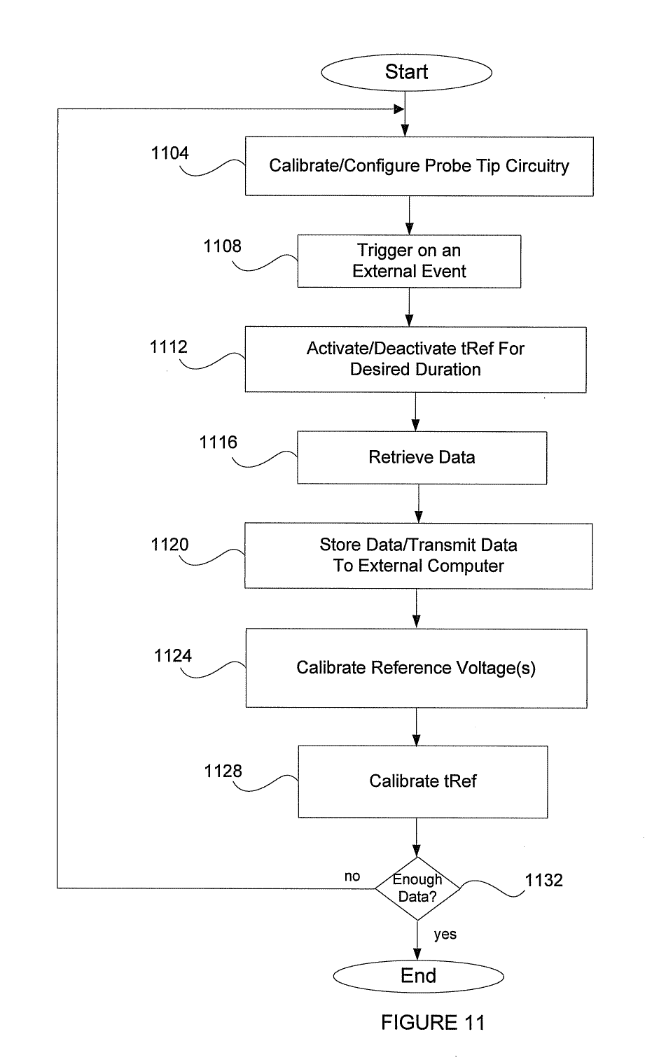

FIG. 11 is an operational flow diagram of a method for measuring one or more parameters of a signal in an integrated circuit chip in accordance with an embodiment of the invention. The integrated circuit chip may comprise an application specific integrated circuit (ASIC), for example. At step 1104, one or more probes in the integrated circuit chip are calibrated and/or configured for monitoring and measuring one or more parameters of a signal. The one or more parameters may comprise a voltage, a duty cycle, a period or cycle of a clock, and jitter, for example. Next, at step 1108, the start of measurement is triggered by an external event. The external event may comprise a power up of the integrated circuit chip, for example. Thereafter, at step 1112, a timing control signal is generated by external test equipment. The pulse width or duty cycle of the timing control signal, tRef, is determined for the desired duration of measurement. Next, at step 1116, the one or more probes are used to retrieve the measured parameters. At step 1120, the retrieved data may be stored into memory and/or transmitted to an external test equipment and/or external computer for further processing. The one or more parameters may be used to refine and/or correct the fabrication process used in manufacturing the integrated circuit chip. The computer may perform statistical analysis of the data which may be presented to a user of the external test equipment and/or computer. The process proceeds at step 1124 where the reference voltages provided to the integrated circuit chip may be calibrated using a comparator situated in the integrated circuit chip. Furthermore, at step 1128, the tRef signal measured by the one or more probes may be calibrated using the known tRef signal waveform provided by the external test equipment. At step 1132, a decision is made whether enough data measurements have been obtained. If so, the process ends. Otherwise, the process continues at step 1104.

The various aspects of the present invention may be realized in the form of hardware, software, or a combination thereof. The hardware may comprise one or more circuits capable of implementing the methods, functionalities, and/or operations previously described in connection with the figures.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiments disclosed, but that the invention will include all embodiments falling within the scope of the appended claims.

What is claimed is:

1. A method comprising:
receiving a first voltage, a second voltage, and a control signal, said first voltage used for powering a probe, said second voltage used as a voltage reference for voltage measurement by said probe, wherein said probe is located within an integrated circuit chip; and
measuring one or more parameters within said integrated circuit chip using said first voltage, said second voltage, and said control signal, said one or more parameters comprising one or more of:
minimum and maximum voltage levels of a signal,
a series of sampled voltage levels of a signal,
a period of a signal, and
a jitter of said signal.

2. The method of claim 1 wherein said signal comprises a clock signal used in said integrated circuit chip.

3. The method of claim 1 wherein said one or more parameters further comprises temperature.

4. The method of claim 1 wherein said one or more parameters further comprises a duty cycle of said signal.

5. The method of claim 1 further comprising transmitting said one or more parameters over a debug interface to a processor external to said integrated circuit chip.

6. The method of claim 1 further comprising transmitting said one or more parameters to a processor over an interface internal to said integrated circuit chip.

7. The method of claim 1 wherein said probe comprises a ring oscillator for generating a clock signal used in measuring said one or more parameters.

8. The method of claim 1 wherein said probe comprises:
a ring oscillator; and
a register, containing a series of paired flip-flops, sampled at a frequency equal to a frequency of said ring oscillator times the number of delay elements used in said ring oscillator.

9. An integrated circuit chip comprising:
one or more circuits for, at least:
receiving a first voltage, a second voltage, and a control signal, said first voltage used for powering said one or more circuits, said second voltage used as a voltage reference for voltage measurement within said integrated circuit chip;
measuring one or more parameters within said integrated circuit chip using said first voltage, said second voltage, and said control signal, said one or more parameters comprising one or more of:
minimum and maximum voltage levels of a signal,
a series of sampled voltage levels of a signal,
a period of a signal, and
a jitter of said signal.

10. The integrated circuit chip of claim 9 wherein said signal comprises a clock used in said integrated circuit chip.

11. The integrated circuit chip of claim 9 wherein said one or more parameters further comprises temperature.

12. The integrated circuit chip of claim 9 wherein said one or more parameters further comprises a duty cycle.

13. The integrated circuit chip of claim 9 further comprising transmitting said one or more parameters over a debug interface to a processor external to said integrated circuit chip.

14. The integrated circuit chip of claim 9 further comprising transmitting said one or more parameters to a processor over an interface internal to said integrated circuit chip.

15. The integrated circuit chip of claim 9 wherein said one or more circuits comprises a ring oscillator for generating a clock signal used in measuring said one or more parameters.

16. The integrated circuit chip of claim 9 wherein said one or more circuits comprises:
a ring oscillator; and
a register, containing a series of paired flip-flops, sampled at a frequency equal to the frequency of said ring oscillator times the number of delay elements used in said ring oscillator.

17. An integrated circuit chip comprising:
at least one probe for measuring one or more signal parameters within said integrated circuit chip;
a memory for storing data obtained from said measuring;
a probe control circuitry for configuring and controlling said at least one probe;
a first interface for communicatively coupling said at least one probe to a computer external to said integrated circuit chip for allowing processing of said data by said computer, said probe control circuitry communicatively coupled to said at least one probe and said first interface; and
a second interface communicatively coupled to said probe control circuitry and a processor within said integrated circuit chip, wherein said processor processes said data obtained from said measuring.

18. The integrated circuit chip of claim 17 wherein said probe comprises a ring oscillator, said ring oscillator comprising a number of delay elements, wherein inverted and non-inverted outputs of said delay elements are presented as inputs to a plurality of flip-flop pairs in each of a plurality of registers.

19. The integrated circuit of claim 17 wherein said second interface transmits data for determining temperature at a ring oscillator in said at least one probe.

20. The integrated circuit of claim 17 wherein said at least one probe is periodically calibrated with respect to clock jitter measurement.

21. The integrated circuit of claim 17 wherein a first voltage, a second voltage, and a control signal is received by said at least one probe, said first voltage used for powering said at least one probe, said second voltage used as a voltage reference for voltage measurement within said integrated circuit chip, and wherein said first voltage and said second voltage are periodically calibrated at each of said at least one probe.
